(19) United States
(12) Patent Application Publication
(10) Pub. No.: US 2017/0250365 A1
(43) Pub. Date: Aug. 31, 2017

(54) PACKAGE STRUCTURE OF AND PACKAGING METHOD FOR ARRAY SUBSTRATE AND DISPLAY PANEL

(71) Applicants: SHANGHAI TIANMA AM-OLED CO., LTD., Shanghai (CN); TIANMA MICRO-ELECTRONICS CO., LTD., Shenzhen (CN)

(72) Inventors: Jian JIN, Shanghai (CN); Congyi SU, Shanghai (CN)

(21) Appl. No.: 15/209,255

(22) Filed: Jul. 13, 2016

(30) Foreign Application Priority Data
Feb. 29, 2016 (CN) 201610112413.8

(51) Int. Cl. H01L 51/52; H01L 51/56; H01L 27/32

(52) U.S. Cl. CPC H01L 51/5237; H01L 27/3244; H01L 51/5253; H01L 51/56; H01L 2227/323

(57) ABSTRACT

A package structure of and a packaging method for an array substrate and a display panel including the package structure for the array substrate are provided. The package structure includes: the array substrate, where multiple organic light emitting display units are formed in a display region of the array substrate; a first inorganic film layer covering the multiple organic light emitting display units, located in the display region; a bump structure, located on a periphery of the display region; and an organic film layer, located on a surface of the first inorganic film layer away from the array substrate. A thickness of the organic film layer is greater than a height of the bump structure, and a surface of the bump structure has repellence against formation solution, so that the organic film layer completely covers the display region and the formation solution does not overflow the bump structure.

### CROSS REFERENCES OF RELATED APPLICATION

The present application claims the priority to Chinese Patent Application No. 201610112413.8, entitled “PACKAGE STRUCTURE OF AND PACKAGING METHOD FOR ARRAY SUBSTRATE AND DISPLAY PANEL”, filed on Feb. 29, 2016 with the State Intellectual Property Office of the People's Republic of China, which is incorporated herein by reference in its entirety.

### TECHNICAL FIELD

The present disclosure relates to the technical field of display, and in particular to a package structure of and a packaging method for an array substrate and a display panel including the package structure of the array substrate.

### BACKGROUND

With the development of display technology, an increasing number of array substrates are packaged with a thin film packaging technology, so as to improve flexibility of package structures of the array substrates. As shown in FIG. 1, a conventional package structure for an array substrate packaged with the thin film packaging technology includes: a first substrate 01, where multiple organic light emitting display units (which is not illustrated in the figure) are formed in a display region on a surface of the first substrate 01; a first inorganic film 02 covering the multiple organic light emitting display units, located in the display region on the surface of the first substrate 01; an organic film 04 covering the first inorganic film 02, located in the display region on a side of the first inorganic film 02 away from the first substrate 01; and a second inorganic film 05 covering the organic film 04 and the first substrate 01, located in the display region on a side of the organic film 04 away from the first inorganic film 02 and a border region; where a barrier structure 03 is arranged on a boundary of the organic film 04, so as to ensure that the organic film 04 is formed only in the display region without extending to the border region.

At present, in a specific packaging process of the array substrate, the barrier structure 03 is formed on a boundary between the display region and the border region of the first substrate 01. Then, the organic film 04 is formed in the display region encircled by the barrier structure 03. A method for forming the organic film 04 includes: depositing, droplets of formation ink of the organic film 04, in the display region encircled by the barrier structure 03, with an inkjet printing technology. The droplets flow together and form a continuous liquid thin film. Then the continuous liquid thin film is cured, to form the organic film.

In practice, in the packaging process of the array substrate, in certain situations, organic film 04 may form to cover the barrier structure 03 and extend to the border region (which is illustrated in FIG. 2). In certain situations, a boundary of the organic film 04 may have a distance from the barrier structure 03 and thus does not completely cover the display region (which is illustrated in FIG. 3). These can affect a quality of the package structure for the array substrate.

### SUMMARY

In order to solve the above technical problems, a package structure for and a packaging method for an array substrate and a display panel including the package structure of the array substrate, are provided according to embodiments of the present disclosure, so that quality of the package structure of the array substrate and the display panel can be improved.

In order to solve the above problems, the following technical solutions are provided according to the embodiments of the present disclosure. A package structure for an array substrate is provided, which includes: the array substrate, a first inorganic film layer covering the plurality of organic light emitting display units, a bump structure located on a periphery of the display region of the array substrate, and an organic film layer located on a surface of the first inorganic film layer away from the array substrate in the display region encircled by the bump structure. In a display region of the array substrate, organic light emitting display units are formed. A surface of the bump structure has repellence against formation solution of the organic film layer, and a thickness of the organic film layer is greater than a height of the bump structure.

A method for packaging an array substrate is provided, which includes: providing the array substrate, forming a first inorganic film layer covering the multiple organic light emitting display units, in the display region on the surface of the array substrate, forming a bump structure, on a periphery of the display region of the array substrate, processing a surface of the bump structure so as to enable the surface of the bump structure to have repellence against formation solution of the organic film layer to be formed, forming, an organic film layer, on a surface of the first inorganic film layer away from the array substrate in the display region encircled by the bump structure. In this method, multiple organic light emitting display units are formed in a display region on a surface of the array substrate. Under this method, a thickness of the organic film layer is greater than a height of the bump structure and a forming process for the organic film layer is an inkjet printing process.

In various embodiments, a display panel is provided, which includes the above package structure.

Compared with the conventional technology, the above technical solutions have the following advantages.

The package structure for the array substrate according to the embodiments of the present disclosure includes: the array substrate, the first inorganic film layer covering the multiple organic light emitting display units located in the display region of the array substrate, the bump structure located on the periphery of the display region of the array substrate, and the organic film layer located on the surface of the first inorganic film layer away from the array substrate in the display region encircled by the bump structure. The multiple organic light emitting display units are formed in the display region of the array substrate. The thickness of the organic film layer is greater than the height of the bump structure, so that a phenomenon that the organic film layer does not completely cover the display region is avoided. The surface of the bump structure has repellence against the formation solution of the organic film layer, so that a phenomenon that the formation solution of the organic film layer overflows the bump structure and spreads to a side of the bump structure away from the display region in a case that the thickness of the organic film layer is greater than the height of the bump structure is avoided.

### BRIEF DESCRIPTION OF THE DRAWINGS

In order to more clearly illustrate technical solutions in embodiments of the present disclosure or in the conventional technology, drawings used in the description of the embodiments or the conventional technology are introduced briefly hereinafter. Apparently, the drawings described in the following illustrate some embodiments of the present disclosure, and other drawings may be obtained by those ordinarily skilled in the art based on these drawings without any creative efforts.

FIG. 1 is a schematic structural diagram of a package structure for an array substrate in the conventional technology;

FIG. 2 is a schematic diagram of an organic film layer spreading over a blocking wall in a package structure for an array substrate in the conventional technology;

FIG. 3 is a schematic diagram of an organic film layer having a distance from a blocking wall in a package structure for an array substrate in the conventional technology;

FIG. 4 is a schematic structural diagram of a package structure for an array substrate according to an embodiment of the present disclosure;

FIG. 5 is a schematic diagram of there being a droplet of formation solution of an organic film layer on a surface of an array substrate in a package structure of the array substrate according to an embodiment of the present disclosure;

FIG. 6 is a schematic partial structural diagram of a package structure for an array substrate according to an embodiment of the present disclosure;

FIG. 7 is a schematic structural diagram of a package structure for an array substrate according to an embodiment of the present disclosure;

FIG. 8 is a schematic flow chart of a method for packaging an array substrate according to an embodiment of the present disclosure;

FIG. 9 is a schematic flow chart of a method for packaging an array substrate according to an embodiment of the present disclosure;

FIG. 10 is a schematic structural diagram of a package structure for an array substrate according to an embodiment of the present disclosure;

FIG. 11 is a schematic structural diagram of a package structure for an array substrate according to an embodiment of the present disclosure; and

FIG. 12 is a schematic diagram of a display panel according to an embodiment of the present disclosure.

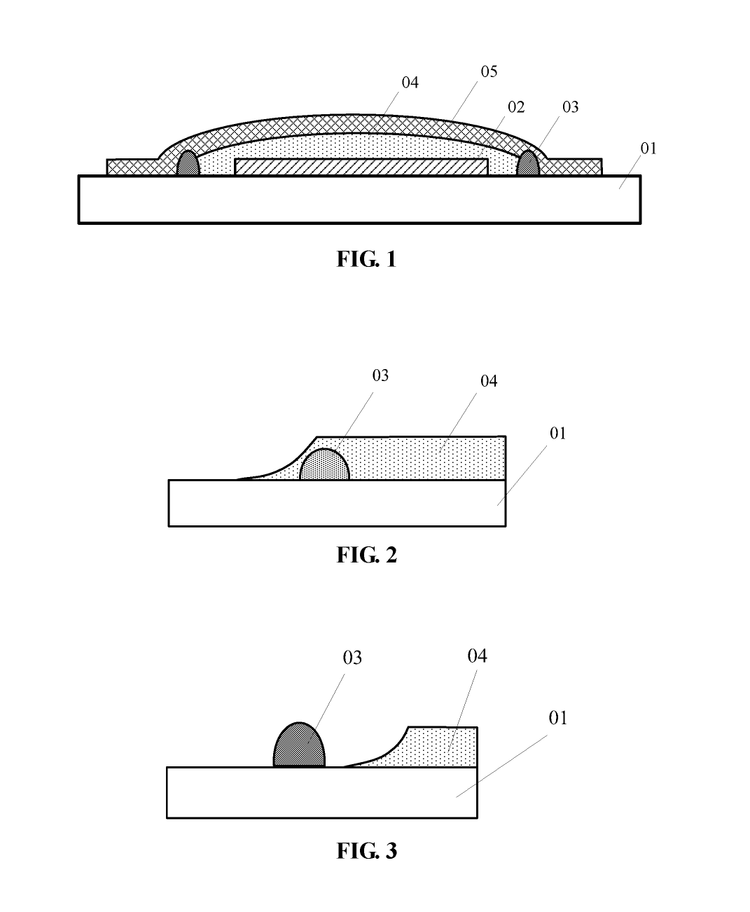

### DETAILED DESCRIPTION OF THE EMBODIMENTS

As described in the background, in the packaging process of the array substrate, the phenomenon that the organic film covers the barrier structure and extends to the border region or the phenomenon that the boundary of the organic film has a distance from the barrier structure and the organic film does not completely cover the display region, may usually occur due to being limited by the process precision, which affects the quality of the package structure of the array substrate.

In view of this, a package structure for an array substrate is provided according to an embodiment of the present disclosure, which includes: the array substrate, a first inorganic film layer covering the plurality of organic light emitting display units, a bump structure located on a periphery of the display region of the array substrate, and an organic film layer located on a surface of the first inorganic film layer away from the array substrate in the display region encircled by the bump structure. In a display region of the array substrate, organic light emitting display units are formed. A surface of the bump structure has repellence against formation solution of the organic film layer, and a thickness of the organic film layer is greater than a height of the bump structure.

Accordingly, a method for packaging an array substrate is provided according to an embodiment of the present disclosure, which includes: providing the array substrate, forming a first inorganic film layer covering the multiple organic light emitting display units, in the display region on the surface of the array substrate, forming a bump structure, on a periphery of the display region of the array substrate, processing a surface of the bump structure so as to enable the surface of the bump structure to have repellence against formation solution of the organic film layer to be formed, forming, an organic film layer, on a surface of the first inorganic film layer away from the array substrate in the display region encircled by the bump structure. In this method, multiple organic light emitting display units are formed in a display region on a surface of the array substrate. Under this method, a thickness of the organic film layer is greater than a height of the bump structure and a forming process for the organic film layer is an inkjet printing process.

In addition, a display panel including the above package structure of the array substrate is provided according to an embodiment of the present disclosure.

In the package structure of and the packaging method for the array substrate and the display panel including the package structure of the array substrate according to the embodiments of the present disclosure, the thickness of the organic film layer is greater than the height of the bump structure, so that a phenomenon that the organic film layer does not completely cover the display region is avoided. In addition, the surface of the bump structure has repellence against the formation solution of the organic film layer, so that a phenomenon that the formation solution of the organic film layer overflows the bump structure and spreads to a side of the bump structure away from the display region in a case that the thickness of the organic film layer is greater than the height of the bump structure is avoided.

The technical solutions in embodiments of the present disclosure are clearly and completely described hereinafter in conjunction with the drawings in the embodiments of the present disclosure. Apparently, the described embodiments are only a few of the embodiments of the present disclosure. Based on the embodiments of the present disclosure, all other embodiments obtained by those ordinarily skilled in the art without any creative efforts fall within the protection scope of the present disclosure.

Specific details are described in the following descriptions, so as to fully understand the present disclosure. The present disclosure may be implemented in other manners different from those described herein, similar promotions can be made by those skilled in the art without departing from the essence of the present disclosure. Hence, the present disclosure is not limited by the embodiments disclosed in the following.

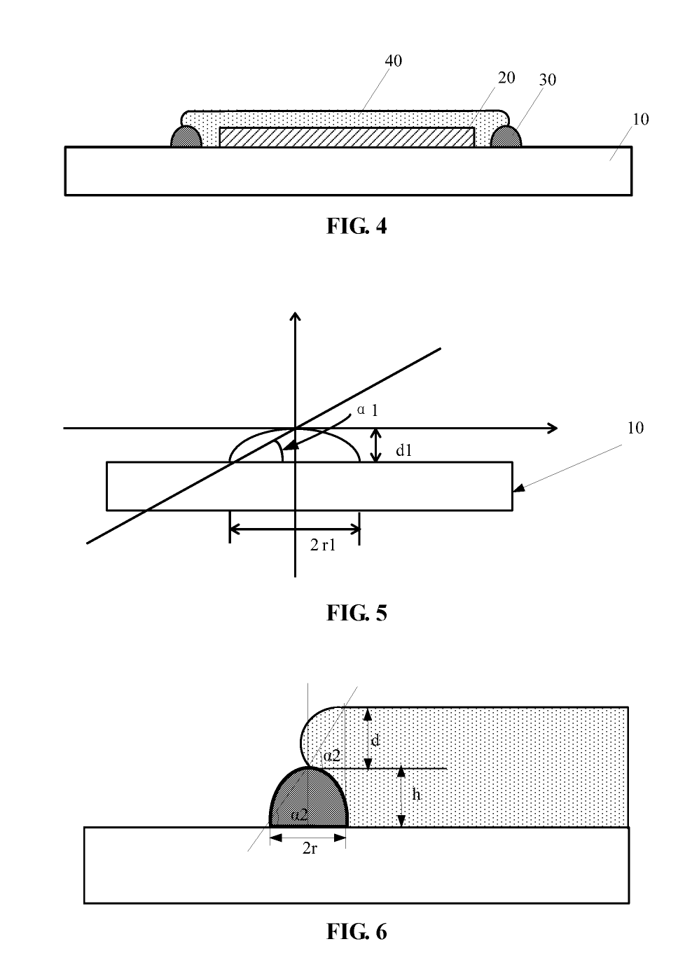

Reference is made to FIG. 4, which is a schematic structural diagram of a package structure for an array substrate according to an embodiment of the present disclosure. As shown in FIG. 4, the package structure of the array substrate according to the embodiment of the present disclosure includes: the array substrate 10, a first inorganic film layer 20 covering the multiple organic light emitting display units located in the display region of the array substrate 10; a bump structure 30 located on a periphery of the display region of the array substrate 10; and an organic film layer 40 located on a surface of the first inorganic film layer 20 away from the array substrate in the display region encircled by the bump structure 30. Multiple organic light emitting display units are formed in a display region of the array substrate 10 (which is not illustrated in the figure). A surface of the bump structure 30 has repellence against formation solution of the organic film layer 40, and a thickness of the organic film layer 40 is greater than a height of the bump structure 30. It should be noted that, in this embodiment, the bump structure 30 includes a blocking wall structure, the blocking wall structure is located on the periphery of display region, and a surface of the blocking wall structure has repellence against the formation solution of the organic film layer 40. The periphery of the display region refers to a margin around the display region.

On the basis of the above embodiment, in an embodiment of the present disclosure, a difference d between the thickness of the organic film layer 40 and the height of the bump structure 30 meets the following criteria: 0<d<h, so as to ensure that the thickness of the organic film layer 40 is greater than the height of the bump structure 30 and that the formation solution of the organic film layer 40 will not spread to a side of the bump structure 30 away from the display region and affect quality of the package structure of the array substrate in a forming process of the organic film layer 40, wherein, h is the height of the bump structure 30.

As shown in FIG. 5, a radius of a droplet of the formation solution of the organic film layer 40 is r1, a height of the droplet is h1, and an angle α1 between a line between a highest point of the droplet of the solution and a rim thereof and a surface of the array substrate 10 meets the following relation: tan α1=h1/r1. As shown in FIG. 6, tan α2=h/r=h/d. It can be seen that, in the embodiment, the formation solution of the organic film layer 40 will not spread to the side of the bump structure 30 away from the display region in the forming process of the organic film layer 40 as long as the difference d between the thickness of the organic film layer 40 and the height of the bump structure 30 is not greater than the height h of the bump structure 30, since the surface of the bump structure 30 has repellence against the formation solution of the organic film layer 40.

On the basis of the above embodiment, in another embodiment, the difference d between the thickness of the organic film layer 40 and the height of the bump structure 30 meets the following criteria: 10%≦d/h≦50%, so as to reduce usage amount of the formation solution of the organic film layer 40 and reduce a cost of the organic film layer 40 on the basis of ensuring that the organic film layer 40 can completely cover the display region and will not extend to the side of the bump structure 30 away from the display region, thereby reducing a cost of the package structure of the array substrate. It should be noted that, a minimum value 10% of the d/h is process precision of a device used for forming the organic film layer 40 in the embodiment, and the minimum value of the d/h changes accordingly if the process precision of the device used for forming the organic film layer 40 changes in another embodiment, which is not limited herein as long as it is ensured that the minimum value of the d/h is not less than the process precision of the device used for forming the organic film layer 40.

On the basis of any one of the above embodiments, in an optional embodiment of the present disclosure, a range of the height h of the bump structure 30 is 0 μm<h≦20 μm, which is not limited herein and depends on specific situations.

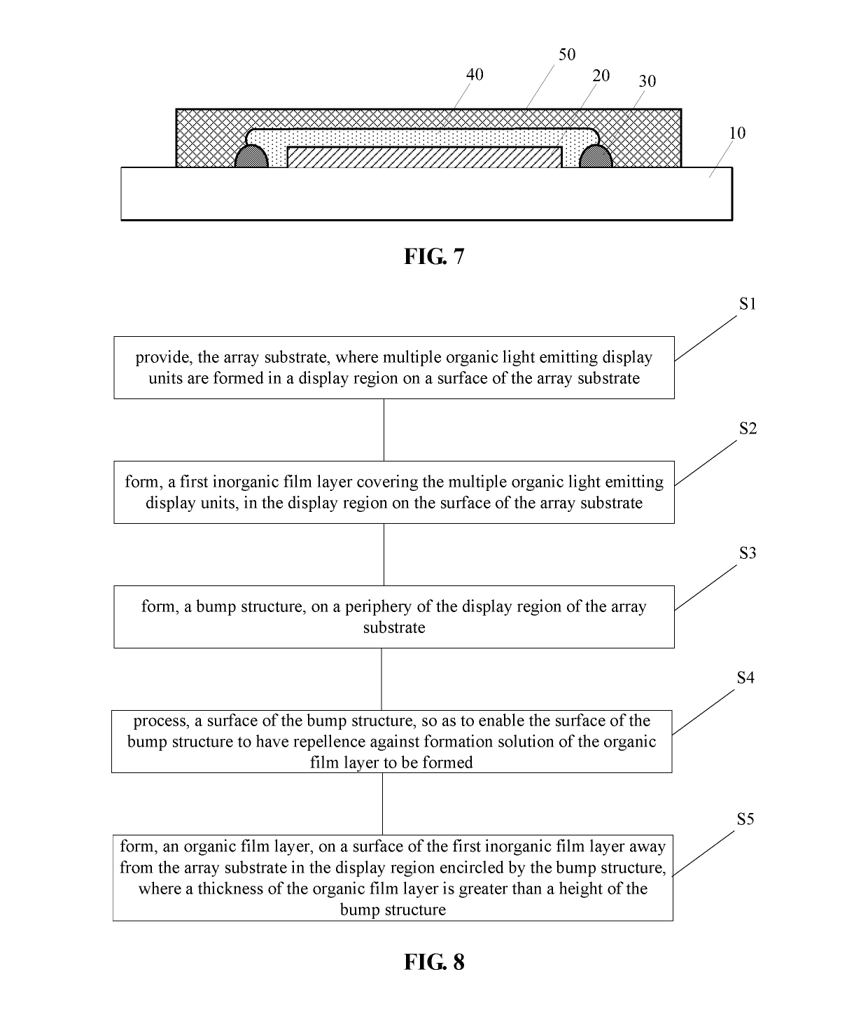

On the basis of any one of the above embodiments, in an embodiment of the present disclosure, the package structure of the array substrate further includes: a second inorganic film layer 50, located on a side of the organic film layer 40 away from the first inorganic film layer 20, as shown in FIG. 7.

In any one of the above embodiments, optionally, material of the blocking wall structure is polyimide or polymethacrylate, and so on. Material of the organic film layer 40 is transparent organic matter with small stress and high flatness, such as acryl (such as polymethacrylate); and material of the first inorganic film layer 20 and the second inorganic film layer 50 is inorganic matter that can block moisture and oxygen, such as SiN_{X}, Al₂O₃, SiO₂ and SiNO, which is not limited herein and depends on specific situations.

Accordingly, a method for packaging an array substrate applied to a package structure of the array substrate according to any one of the above embodiments, is provided according to an embodiment of the present disclosure. As shown in FIG. 8, the packaging method includes steps S1 to S5. In step S1, the array substrate is provided, where multiple organic light emitting display units are formed in a display region on a surface of the array substrate. In step S2, a first inorganic film layer covering the multiple organic light emitting display units is formed, in the display region on the surface of the array substrate. In step S3, a bump structure is formed, on a periphery of the display region of the array substrate. In step S4, a surface of the bump structure is processed, so as to enable the surface of the bump structure to have repellence against formation solution of the organic film layer to be formed. In step S5, an organic film layer is formed, on a surface of the first inorganic film layer away from the array substrate in the display region encircled by the bump structure, where a thickness of the organic film layer is greater than a height of the bump structure. A forming process for the organic film layer is an inkjet printing process.

It should be noted that, in the embodiment of the present disclosure, the bump structure includes a blocking wall structure, and a surface of the blocking wall structure has repellence against the formation solution of the organic film layer. Specifically, in the embodiment of the present disclosure, the forming a bump structure on a periphery of the display region of the array substrate includes: forming the blocking wall structure, on the periphery of the display region of the array substrate. In some embodiments, the processing of a surface of the bump structure so as to enable the surface of the bump structure to have repellence against formation solution of the organic film layer to be formed includes: processing, a surface of the blocking wall structure, so as to enable the surface of the blocking wall structure to have repellence against the formation solution of the organic film layer to be formed.

On the basis of the above embodiment, in some embodiments, the forming, the blocking wall structure, on the periphery of the display region of the array substrate includes: forming at least one insulating layer, on the periphery of the display region of the array substrate, and etching the at least one insulating layer to form the blocking wall structure on the periphery of the display region of the array substrate. In another embodiment of the present disclosure, the forming of the blocking wall structure on the periphery of the display region of the array substrate includes: directly forming the blocking wall structure, on the periphery of the display region of the array substrate, with a printing process. In another embodiment of the present disclosure, the blocking wall structure may be formed on the periphery of the display region of the array substrate with another method, which is not limited herein and depends on specific situations.

On the basis of any one of the above embodiments, the processing of the surface of the bump structure can include: processing the surface of the bump structure, with plasma, so as to enable the surface of the bump structure to have repellence against the formation solution of the organic film layer; and in another embodiment of the present disclosure, the processing the surface of the bump structure includes: irradiating, the surface of the bump structure, with ultraviolet radiation, so as to enable the surface of the bump structure to have repellence against the formation solution of the organic film layer. In another embodiment of the present disclosure, the surface of the bump structure may be processed with another method, so as to enable the surface of the bump structure to have repellence against the formation solution of the organic film layer, which is not limited herein and depends on specific situations.

It should be noted that, in the above embodiment, the plasma optionally may be plasma of a gas mixture of a gas with fluoro and an oxygen gas or plasma of an oxygen gas.

It should be noted that, in a specific process of implementing the packaging method according to the embodiments of the present disclosure, the first inorganic film layer is formed in the display region of the array substrate, and then the bump structure is formed on the periphery of the display region of the array substrate; or, the bump structure is formed on the periphery of the display region of the array substrate, and then the first inorganic film layer is formed in the display region of the array substrate, which is not limited herein and depends on specific situations.

On the basis of any one of the above embodiments, the forming of an organic film layer, on a surface of the first inorganic film layer away from the array substrate in the display region encircled by the bump structure, with a thickness of the organic film layer being greater than a height of the bump structure can include: calculating, a volume of droplets needed by the organic film layer to be formed, based on the height of the bump structure. The method can also include setting an actual volume of the droplets needed by the organic film layer to be formed, based on the calculated volume of the droplets needed by the organic film layer to be formed, with the actual volume of the droplets needed by the organic film layer to be formed being larger than the volume of the droplets needed by the organic film layer to be formed so as to enable the thickness of the subsequently formed organic film layer to be greater than the height of the bump structure. Forming the organic film layer, on the surface of the first inorganic film layer away from the array substrate in the display region encircled by the bump structure, based on the actual volume of the droplets needed by the organic film layer to be formed.

In some embodiments, on the basis of the above embodiment, the setting of an actual volume of the droplets needed by the organic film layer to be formed, based on the volume of the droplets needed by the organic film layer to be formed, with the actual volume of the droplets needed by the organic film layer to be formed being larger than the volume of the droplets needed by the organic film layer to be formed, includes: calculating, the number of the droplets needed by the organic film layer to be formed and an volume of each of the droplets, based on the calculated volume of the droplets needed by the organic film layer to be formed and parameters of a device used for forming the organic film layer to be formed. The method can also include setting the actual number of the droplets needed by the organic film layer to be formed and an actual volume of the each of the droplets, based on the calculated number of the droplets needed by the organic film layer to be formed and the volume of the each of the droplets, so as to enable the actual volume of the droplets needed by the organic film layer to be formed to be larger than the volume of the droplets needed by the organic film layer to be formed.

Specifically, on the basis of the above embodiment, the actual number of the droplets needed by the organic film layer to be formed is equal to the number of the droplets needed by the organic film layer to be formed, and the actual volume of the each of the droplets is larger than the volume of the each of the droplets, so as to enable the actual volume of the droplets needed by the organic film layer to be formed to be larger than the volume of the droplets needed by the organic film layer to be formed. In another embodiment of the present disclosure, the actual volume of the each of the droplets is equal to the volume of the each of the droplets, and the actual number of the droplets needed by the organic film layer to be formed is greater than the number of the droplets needed by the organic film layer to be formed, so as to enable the actual volume of the droplets needed by the organic film layer to be formed to be larger than the volume of the droplets needed by the organic film layer to be formed. In another embodiment, the actual number of the droplets needed by the organic film layer to be formed is greater than the number of the droplets needed by the organic film layer to be formed. The actual volume of the each of the droplets is larger than the volume of the each of the droplets, so as to enable the actual volume of the droplets needed by the organic film layer to be formed to be larger than the volume of the droplets needed by the organic film layer to be formed, which is not intended to be limited as long as it is ensure that the actual volume of the droplets needed by the organic film layer to be formed is larger than the volume of the droplets needed by the organic film layer to be formed.

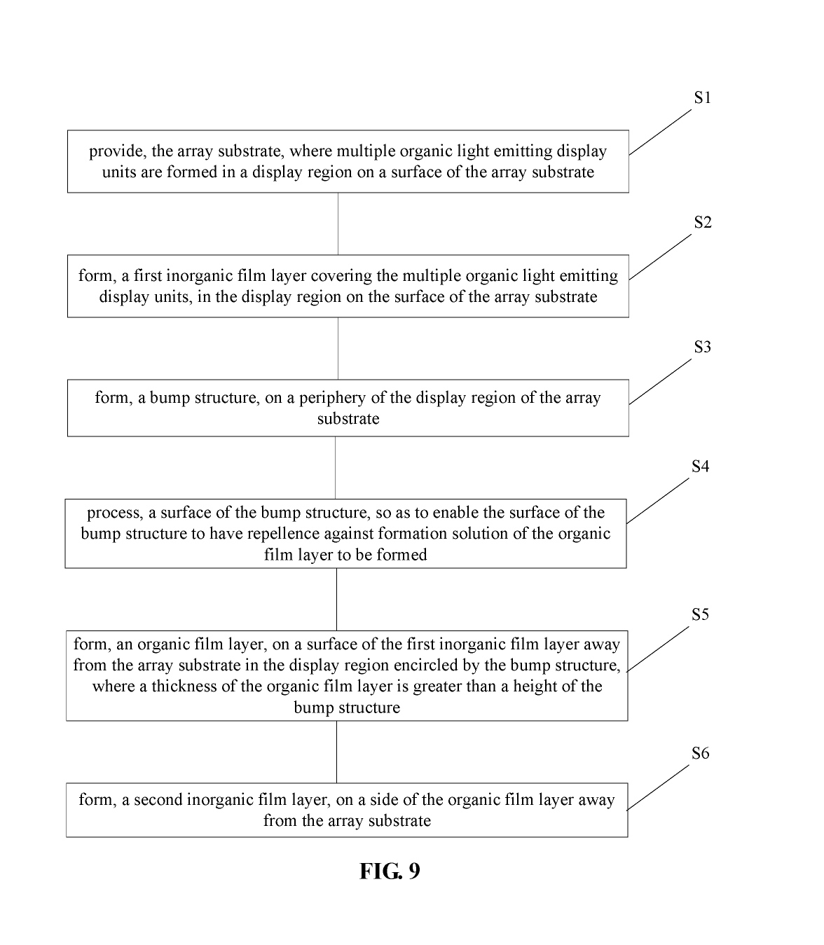

On the basis of any one of the above embodiments, in an embodiment of the present disclosure, the method for packaging the array substrate further includes step S6, as shown in FIG. 9. In step S6, a second inorganic film layer is formed, on a side of the organic film layer away from the array substrate.

In the package structure for and the packaging method for the array substrate according to the embodiments of the present disclosure, the thickness of the organic film layer is greater than the height of the bump structure, so that a phenomenon that the organic film layer does not completely cover the display region is avoided. In addition, the surface of the bump structure has repellence against the formation solution of the organic film layer, so that a phenomenon that the formation solution of the organic film layer overflows the bump structure and spreads to a side of the bump structure away from the display region in a case that the thickness of the organic film layer is greater than the height of the bump structure is avoided.

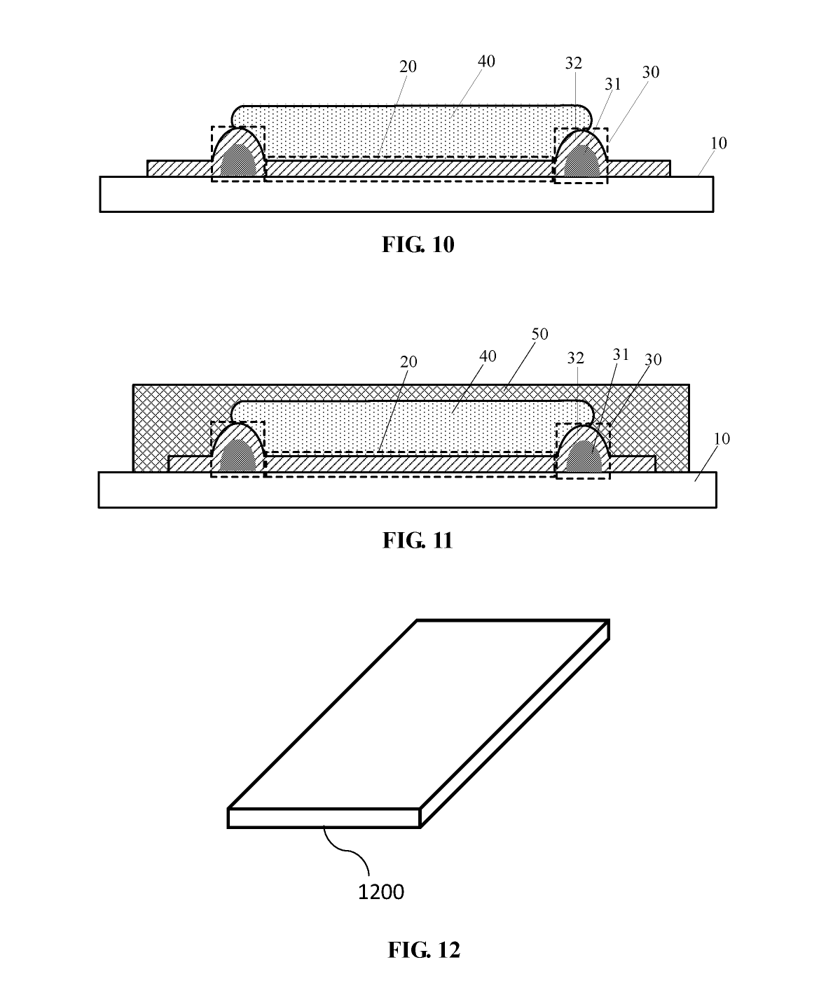

In addition, another schematic structural diagram of a package structure for an array substrate is provided according to an embodiment of the present disclosure. Reference is made to FIG. 10, which is the schematic structural diagram of the package structure of the array substrate according to the embodiment of the present disclosure. In the package structure of the array substrate according to the embodiment, other structures than a bump structure are the same as those in the above package structure of the array substrate. As shown in FIG. 10, the package structure of the array substrate according to the embodiment includes: the array substrate 10, where multiple organic light emitting display units are formed in a display region of the array substrate 10; a first inorganic film layer 20 covering the multiple organic light emitting display units, located in the display region of the array substrate 10; a bump structure 30, located on a periphery of the display region of the array substrate 10; and an organic film layer 40, located on a surface of the first inorganic film layer 20 away from the array substrate in the display region encircled by the bump structure 30; where a surface of the bump structure 30 has repellence against formation solution of the organic film layer 40, and a thickness of the organic film layer 40 is greater than a height of the bump structure 30. The bump structure 30 includes: a blocking wall structure 31 and an inorganic covering film layer 32 located on a surface of the blocking wall, where a surface of the inorganic covering film layer 32 has repellence against the formation solution of the organic film layer 40. Optionally, the inorganic covering film layer 32 and the first inorganic film layer 20 are formed at the same time.

On the basis of the above embodiments, in an embodiment of the present disclosure, the package structure of the array substrate further includes: a second inorganic film layer 50, located on a side of the organic film layer 40 away from the first inorganic film layer 20, as shown in FIG. 11.

Accordingly, another method for packaging an array substrate applied to the above package structure of the array substrate, is further provided according to an embodiment of the present disclosure. In the method for packaging the array substrate according to the embodiment, methods for forming other structures than a bump structure and a first inorganic film layer are the same as those in the above method for packaging the array substrate. Specifically, in the embodiment of the present disclosure, the method for packaging the array substrate includes steps S1 to S5. In step S1, the array substrate is provided, where multiple organic light emitting display units are formed in a display region on a surface of the array substrate. In step S2, a first inorganic film layer covering the multiple organic light emitting display units is formed, in the display region on the surface of the array substrate. In step S3, a bump structure is formed, on a periphery of the display region of the array substrate. In step S4, a surface of the bump structure is processed, so as to enable the surface of the bump structure to have repellence against formation solution of the organic film layer to be formed. In step S5, an organic film layer is formed, on a surface of the first inorganic film layer away from the array substrate in the display region encircled by the bump structure, where a thickness of the organic film layer is greater than a height of the bump structure. A forming process for the organic film layer is an inkjet printing process.

It should be noted that, in the embodiment of the present disclosure, the bump structure includes: a blocking wall structure and an inorganic covering film layer located on a surface of the blocking wall, where a surface of the inorganic covering film layer has repellence against the formation solution of the organic film layer. Hence, in the embodiment, the forming a bump structure on a periphery of the display region of the array substrate includes: forming, the blocking wall structure, on the periphery of the display region of the array substrate; and forming, the inorganic covering film layer, on the surface of the blocking wall, where the inorganic covering film layer and the first inorganic film layer are formed at the same time. Accordingly, the processing a surface of the bump structure, so as to enable the surface of the bump structure to have repellence against the formation solution of the organic film layer to be formed includes: processing, the surface of the inorganic covering film layer, so as to enable the surface of the inorganic covering film layer to have repellence against the formation solution of the organic film layer to be formed.

It should be noted that, in a specific process of implementing the method for packaging the array substrate according to the embodiment, the blocking wall structure is formed on the periphery of the display region of the array substrate, and then an inorganic film layer is formed in the display region of the substrate and on the surface of blocking wall structure. The inorganic film layer located in the display region of the array substrate is the first inorganic film layer, and the inorganic film layer located on the surface of blocking wall structure is the inorganic covering film layer. In another embodiment of the present disclosure, the first inorganic film layer and the inorganic covering film layer may be formed at different times, which is not limited herein and depends on specific situations.

In addition, FIG. 12 shows a display panel 1200 including a package structure for an array substrate according to any one of the above embodiments.

In conclusion, in the package structure of and the packaging method for the array substrate and the display panel including the package structure of the array substrate according to the embodiments of the present disclosure, the thickness of the organic film layer is greater than the height of the bump structure, so that a phenomenon that the organic film layer does not completely cover the display region is avoided. In addition, the surface of the bump structure has repellence against the formation solution of the organic film layer, so that a phenomenon that the formation solution of the organic film layer overflows the bump structure and spreads to a side of the bump structure away from the display region in a case that the thickness of the organic film layer is greater than the height of the bump structure is avoided.

The embodiments of the present disclosure are described in a progressive way, the differences from other embodiments are emphatically illustrated in each of the embodiments, and reference can be made to other embodiments for understanding the same or similar parts of the embodiments.

It should be noted that, relational terms in the present disclosure such as the first or the second are only used to differentiate one entity or operation from another entity or operation rather than require or indicate any actual relation or sequence among the entities or operations. In addition, terms such as “include”, “comprise” or any other variants are meant to cover non-exclusive enclosure, so that the process, method, item or device comprising a series of elements not only include the elements but also include other elements which are not specifically listed or the inherent elements of the process, method, item or device. With no other limitations, the element restricted by the phrase “include a . . . ” does not exclude the existence of other same elements in the process, method, item or device including the element.

The above descriptions of the disclosed embodiments enable those skilled in the art to practice or use the present disclosure. Various changes to the embodiments are apparent to those skilled in the art, and general principles defined herein may be implemented in other embodiments without departing from the spirit or scope of the present disclosure. Hence, the present disclosure is not limited to the embodiments disclosed herein but is to conform to the widest scope consistent with the principles and novel features disclosed herein.

1. A package structure, comprising:
an array substrate, wherein a plurality of organic light emitting display units are formed in a display region of the array substrate;
a first inorganic film layer covering the plurality of organic light emitting display units, the first inorganic film layer being located in the display region of the array substrate;
a bump structure, located on a periphery of the display region of the array substrate; and
an organic film layer, located on a surface of the first inorganic film layer away from the array substrate in the display region encircled by the bump structure; and, wherein
a surface of the bump structure has repellence against formation solution of the organic film layer, and a thickness of the organic film layer is greater than a height of the bump structure.

2. The package structure according to claim 1, wherein a difference d between the thickness of the organic film layer and the height of the bump structure meets the following criteria: 0<d<h, and h is the height of the bump structure.

3. The package structure according to claim 2, wherein d and h meet the following criteria: 10%≦d/h≦50%.

4. The package structure according to claim 3, wherein h meets the following criteria: 0 μm<h≦20 μm.

5. The package structure according to claim 1, wherein the bump structure comprises a blocking wall structure, and a surface of the blocking wall structure has repellence against the formation solution of the organic film layer.

6. The package structure according to claim 1, wherein the bump structure comprises a blocking wall structure and an inorganic covering film layer located on a surface of the blocking wall, and a surface of the inorganic covering film layer has repellence against the formation solution of the organic film layer.

7. The package structure according to claim 1, further comprising: a second inorganic film layer, located on a side of the organic film layer away from the first inorganic film layer.

8. A method for packaging an array substrate, comprising:
providing the array substrate, wherein a plurality of organic light emitting display units are formed in a display region on a surface of the array substrate;
forming a first inorganic film layer covering the plurality of organic light emitting display units, in the display region on the surface of the array substrate;
forming a bump structure, on a periphery of the display region of the array substrate;
processing a surface of the bump structure, so as to enable the surface of the bump structure to have repellence against formation solution of the organic film layer to be formed; and
forming an organic film layer, on a surface of the first inorganic film layer away from the array substrate in the display region encircled by the bump structure, with a thickness of the organic film layer being greater than a height of the bump structure; and, wherein
a forming process for the organic film layer is an inkjet printing process.

9. The packaging method according to claim 8, wherein the processing the surface of the bump structure comprises: processing the surface of the bump structure, with plasma, or irradiating, the surface of the bump structure, with ultraviolet radiation.

10. The packaging method according to claim 9, wherein the plasma is plasma of a gas mixture of a gas with fluoro and an oxygen gas or plasma of an oxygen gas.

11. The packaging method according to claim 8, wherein the forming of the organic film layer comprises:
calculating a volume of droplets needed by the organic film layer to be formed, based on the height of the bump structure;
setting an actual volume of the droplets needed by the organic film layer to be formed, based on the volume of the droplets needed by the organic film layer to be formed, with the actual volume of the droplets needed by the organic film layer to be formed being larger than the volume of the droplets needed by the organic film layer to be formed; and
forming the organic film layer, on the surface of the first inorganic film layer away from the array substrate in the display region encircled by the bump structure based on the actual volume of the droplets needed by the organic film layer to be formed.

12. The packaging method according to claim 11, wherein the setting of the actual volume of the droplets comprises:
calculating the number of the droplets needed by the organic film layer to be formed and an volume of each of the droplets, based on the calculated volume of the droplets needed by the organic film layer to be formed and parameters of a device used for forming the organic film layer to be formed; and
setting the actual number of the droplets needed by the organic film layer to be formed and an actual volume of the each of the droplets, based on the calculated number of the droplets needed by the organic film layer to be formed and the volume of the each of the droplets, so as to enable the actual volume of the droplets needed by the organic film layer to be formed to be larger than the volume of the droplets needed by the organic film layer to be formed.

13. The packaging method according to claim 12, wherein the actual number of the droplets needed by the organic film layer to be formed is equal to the number of the droplets needed by the organic film layer to be formed, and the actual volume of the each of the droplets is larger than the volume of the each of the droplets; or
the actual volume of the each of the droplets is equal to the volume of the each of the droplets, and the actual number of the droplets needed by the organic film layer to be formed is greater than the number of the droplets needed by the organic film layer to be formed; or
the actual number of the droplets needed by the organic film layer to be formed is greater than the number of the droplets needed by the organic film layer to be formed, and the actual volume of the each of the droplets is larger than the volume of the each of the droplets.

14. The packaging method according to claim 8, wherein the forming the bump structure on the periphery of the display region of the array substrate comprises:
forming a blocking wall structure on the periphery of the display region of the array substrate;
the processing the surface of the bump structure so as to enable the surface of the bump structure to have the repellence against the formation solution of the organic film layer to be formed comprises:
processing a surface of the blocking wall structure, so as to enable the surface of the blocking wall structure to have repellence against the formation solution of the organic film layer to be formed.

15. The packaging method according to claim 8, wherein the forming the bump structure on the periphery of the display region of the array substrate comprises:
forming a blocking wall structure on the periphery of the display region of the array substrate; and
forming an inorganic covering film layer, on the surface of the blocking wall, wherein the inorganic covering film layer and the first inorganic film layer are formed at the same time;
the processing the surface of the bump structure, so as to enable the surface of the bump structure to have repellence against the formation solution of the organic film layer to be formed comprises:
processing a surface of the inorganic covering film layer, so as to enable the surface of the inorganic covering film layer to have repellence against the formation solution of the organic film layer to be formed.

16. The packaging method according to claim 14, wherein the forming of the blocking wall structure comprises:
forming at least one insulating layer, on the periphery of the display region of the array substrate; and
etching the at least one insulating layer, to form the blocking wall structure on the periphery of the display region of the array substrate.

17. The packaging method according to claim 14, wherein the forming of the blocking wall structure comprises:
directly forming the blocking wall structure, on the periphery of the display region of the array substrate, with a printing process.

18. The packaging method according to claim 8, further comprising: forming a second inorganic film layer, on a side of the organic film layer away from the array substrate.

19. A display panel, comprising a package structure, wherein the package structure comprises:
an array substrate, wherein a plurality of organic light emitting display units are formed in a display region of the array substrate;
a first inorganic film layer covering the plurality of organic light emitting display units, located in the display region of the array substrate;
a bump structure, located on a periphery of the display region of the array substrate; and
an organic film layer, located on a surface of the first inorganic film layer away from the array substrate in the display region encircled by the bump structure; and, wherein
a surface of the bump structure has repellence against formation solution of the organic film layer, and a thickness of the organic film layer is greater than a height of the bump structure.
